(19) United States
(12) Patent Application Publication
(10) Pub. No.: US 2007/0241385 A1
(43) Pub. Date: Oct. 18, 2007

(54) Phase change memory device for optimized current consumption efficiency and operation speed and method of manufacturing the same

(76) Inventor: Heon Yong Chang, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/647,926

(22) Filed: Dec. 29, 2006

(30) Foreign Application Priority Data
Apr. 14, 2006 (KR) 10-2006-0034099

(51) Int. Cl. H01L 29/76

(52) U.S. Cl. 257/314

(57) ABSTRACT

Disclosed is a phase change memory device comprising: a semiconductor substrate formed with a first insulating interlayer having a contact hole; a lower electrode formed within the contact hole of the first insulating interlayer; an insulating layer pattern formed on the lower electrode in such a manner so as to be sized smaller than the lower electrode, thereby exposing an edge portion of the lower electrode; a phase change layer formed in such a manner so as to cover the insulating layer pattern and come in contact with the exposed edge portion of the lower electrode; and an upper electrode formed on the phase change layer.

### CROSS-REFERENCES TO RELATED APPLICATION

The present application claims priority to Korean patent application number 10-2006-0034099, filed on Apr. 14, 2006, which is incorporated by reference in its entirety.

### BACKGROUND OF THE INVENTION

The present invention relates to a phase change memory device, and more particularly to a phase change memory device in which the current required for the phase change of a phase change layer can be lowered and operation speed can be improved, and a manufacturing method thereof.

Memory devices are largely divided into Random Access Memory (RAM) and Read Only Memory (ROM) devices. Whereas a RAM device is a volatile memory device that loses input information if power is shut off, the ROM device is a non-volatile memory device that preserves the stored state of input information even in the event of a power shut off. Examples of the volatile RAM device include Dynamic Random Access memory (DRAM) devices and Static Random Access memory(SRAM) devices, and examples of the non-volatile ROM device include flash memory devices such as Electrically Erasable and Programmable ROM (EEPROM) devices.

It is well known in the art that although the DRAM device is a very good memory device, it is difficult to highly integrate because it requires a high charge storage capacity, thus requiring its electrode surface area to be increased. Further, it is also difficult to highly integrate the flash memory device because its laminated structure of two gates requires an operation voltage higher than a power source voltage which necessitates a separate booster circuit to establish a voltage necessary for write and erase operations.

Thereupon, many studies are being pursued to develop new non-volatile memory devices with a simple structure that can be highly integrated. As an example of such memory devices, a phase change memory (in particular, phase change RAM) has recently been proposed.

The phase change memory device is a memory device in which the current flow between upper and lower electrodes causes the phase change layer interposed between the electrodes to undergo a phase change from a crystalline phase to an amorphous phase. The types of information stored in the memory cell are then discerned using the resistance difference according to the phase change of the phase change layer. More specifically, the phase change memory device uses a Chalcogenide layer, that is, a compound layer of Germanium (Ge), Stibium (Sb) and Tellurium (Te), as a phase change layer. Heat generated through the application of a current, that is, so-called Joule heat, causes the Chalcogenide layer to undergo a phase change between a crystalline phase and an amorphous phase. Here, because the phase change layer has a higher resistance when in the amorphous phase as compared to the crystalline phase, the phase change memory device determines whether information stored in a phase change memory cell corresponds to logic “1” or logic “0” by detecting the current flowing through the phase change layer in a read mode.

In such a phase change memory device, the crystalline-to-amorphous phase change of the phase change layer is referred to as “reset” while the amorphous-to-crystalline phase change of the phase change layer is referred to as “set”. In view of current consumption and operation speed, it is optimal for the magnitude of a current inducing the reset/set (programming) to be as low as possible. In order to lower the current required for the phase change of the phase change layer, it is necessary to increase the current density at the contact surface between the phase change layer and the lower electrode by minimizing the contact area therebetween.

Thus, the lower electrode is conventionally formed in the shape of a plug so as to reduce the contact area between the phase change layer and the lower electrode.

However, during the formation of such a plug-shaped lower electrode, the reduction of the contact area between the phase change layer and the lower electrode is limited due to the exposing process. Particularly, when the target size of a plug-shaped lower electrode exceeds the limit of the exposing process, not only is it difficult to form the contact hole for the lower electrode, but the increase in the variation range of the contact hole size makes it difficult to manufacture a phase change memory device with uniform characteristics. Therefore, there is a limitation on lowering the programming current of a phase change memory device and improving its operation speed only by the prior art.

### BRIEF SUMMARY OF THE INVENTION

Embodiments of the present invention are directed to a phase change memory device in which programming current can be lowered and operation speed can be improved, and to a manufacturing method thereof.

In one embodiment of the present invention, there is provided a phase change memory device including: a semiconductor substrate formed with a first insulating interlayer having a contact hole; a lower electrode formed within the contact hole of the first insulating interlayer; an insulating layer pattern formed on the lower electrode in such a manner so as to be smaller than the lower electrode, thereby exposing an edge portion of the lower electrode; a phase change layer formed in such a manner so as to cover the insulating layer pattern and come in contact with the exposed edge portion of the lower electrode; and an upper electrode formed on the phase change layer.

The lower electrode may be formed in the shape of a plug that entirely fills the contact hole.

The lower electrode may be formed in a cylindrical shape along the contact hole surface.

The phase change memory device may further include an insulating layer formed in such a manner so as to fill the contact hole except for a the portion occupied by the cylindrical-shaped lower electrode.

The first insulating interlayer may be made of any one oxide layer selected from the group consisting of TEOS, HDP and HLD layers, and the insulating layer pattern may be made of any one oxide layer selected from the group consisting of HSG, PSG, USG and SOG layers. Alternatively, the first insulating interlayer may be made of an oxide layer, and the insulating layer pattern may be made of a nitride layer.

The phase change memory device may further include a second insulating interlayer formed in such a manner so as to cover the phase change layer and the upper electrode, and a bit line formed on the second insulating interlayer and coming in contact with the upper electrode.

In another embodiment of the present invention, there is provided a method of manufacturing the phase change memory device, the method including the steps of: forming the first insulating interlayerwith a contact hole on a semiconductor substrate; forming a lower electrode within the contact hole; forming an insulating layer pattern on the lower electrode such that the insulating layer pattern is smaller than the lower electrode and exposes an edge portion of the lower electrode; forming a phase change material layer and an electrically conductive layer for an upper electrode in sequence on the first insulating interlayer including the insulating layer pattern; and etching the phase change material layer and the electrically conductive layer for the upper electrode, thereby forming the upper electrode and the phase change layer which covers the insulating layer pattern and comes in contact with the exposed edge portion of the lower electrode.

The lower electrode may be formed in the shape of a plug that entirely fills the contact hole.

The lower electrode may be formed in a cylindrical shape along the contact hole surface.

An insulating layer may be formed in such a manner so as to fill the contact hole except for the contact hole portion occupied by the cylindrical-shaped lower electrode.

The cylindrical-shaped lower electrode and the insulating layer may be formed by the steps of: forming an electrically conductive layer for the lower electrode on the contact hole surface and the first insulating interlayer such that the contact hole is not filled with the electrically conductive layer; forming the insulating layer on the electrically conductive layer for the lower electrode such that the contact hole is filled with the insulating layer; and subjecting the insulating layer and electrically conductive layer for the lower electrode to Chemical Mechanical Polishing (CMP) until the first insulating interlayer is exposed.

The step of forming the insulating layer pattern may include the sub steps of: forming an insulating layer, which is patterned to at least the same size as the lower electrode, on the lower electrode; and isotropically etching a partial thickness of the insulating layer to expose the edge portion of the lower electrode.

The first insulating interlayer may be made of any one oxide layer selected from the group consisting of TEOS, HDP and HLD layers, and the insulating layer pattern may be made of any one oxide layer selected from the group consisting of HSG, PSG, USG and SOG layers. Alternatively, the first insulating interlayer may be made of an oxide layer, and the insulating layer pattern may be made of a nitride layer.

The method of manufacturing a phase change memory device may further include the steps of: after forming the phase change layer and the upper electrode, forming a second insulating interlayer such that the phase change layer and the upper electrode are covered with the second insulating interlayer; and forming a bit line on the second insulating interlayer such that the upper electrode comes in contact with the bit line.

### BRIEF DESCRIPTION OF THE DRAWINGS

FIG. 1 is a cross-sectional view illustrating a phase change memory device in accordance with a preferred embodiment of the present invention;

FIGS. 2A to 2E are cross-sectional views for explaining the method of manufacturing the phase change memory device in accordance with a preferred embodiment of the present invention;

FIG. 3 is a cross-sectional view illustrating a phase change memory device in accordance with another preferred embodiment of the present invention; and

FIGS. 4A to 4E are cross-sectional views for explaining a method of manufacturing a phase change memory device in accordance with another preferred embodiment of the present invention.

### DESCRIPTION OF SPECIFIC EMBODIMENTS

In the present invention, a lower electrode is formed in the shape of a plug, and an insulating layer pattern is formed on the plug-shaped lower electrode such that an upper edge portion thereof is exposed. Further, a phase change layer is formed on the plug-shaped lower electrode including the insulating layer pattern in such a manner so as to cover the insulating layer pattern and come in contact with the edge portion of the exposed plug-shaped lower electrode.

Accordingly, since the phase change layer comes in contact with only the edge portion of the lower electrode, the contact area between the lower electrode and the phase change layer is considerably reduced. Thus, the present invention can reduce the contact area between the lower electrode and the phase change layer while the size of the lower electrode remains similar to that of the prior art, thereby reducing the current required for the phase change of the phase change layer while improving operation speed. Further, since it is unnecessary to reduce the size of the lower electrode to below the limit of the exposing process, the present invention also has an advantage in terms of processes.

More specifically, reference will now be made in detail to a phase change memory device and a manufacturing method thereof with reference to the accompanying drawings.

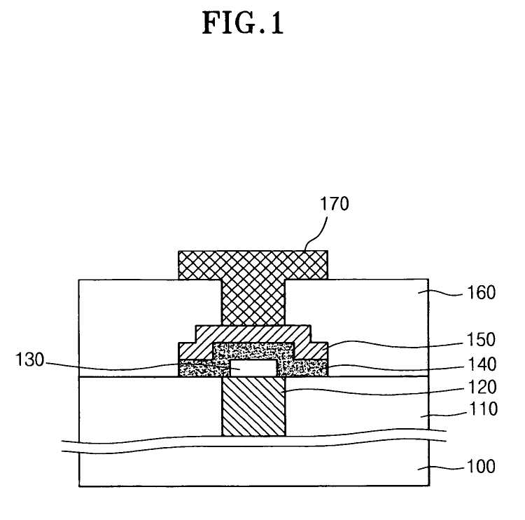

FIG. 1 shows a cross-sectional view of a phase change memory device according to a preferred embodiment of the present invention. The phase change memory device according to this embodiment includes a plug-shaped lower electrode 120, an insulating layer pattern 130 formed on the plug-shaped lower electrode 120 in such a manner so as to expose the edge portion of the plug-shaped lower electrode 120, a phase change layer 140 formed in such a manner so as to cover the insulating layer pattern 130 and come in contact with the edge portion of the plug-shaped lower electrode 120, and an upper electrode 150 formed on the phase change layer 140. The plug-shaped lower electrode 120 is formed within a first insulating interlayer 110 such that the first contact hole is entirely filled with the plug-shaped lower electrode 120. The insulating layer pattern 130 is formed on the middle portion of the plug-shaped lower electrode 120 in such a manner that the edge portion of the plug-shaped lower electrode 120 is exposed.

The phase change memory device of this embodiment further includes a second insulating interlayer 160 formed on the first insulating interlayer 110 in such a manner so as to cover the laminated pattern of the phase change layer 140 and the upper electrode 150, and a bit line 170 formed on the second insulating interlayer 160 and coming in contact with the upper electrode 150.

In the above-described phase change memory device of this embodiment, the contact area between the lower electrode 120 and the phase change layer 140 is significantly reduced because the phase change layer comes in contact with only a portion of the lower electrode 120. Thus, since the phase change memory device of this embodiment has a high current density at the contact surface between the lower electrode 120 and the phase change layer 140, the phase change of the phase change layer 140 is easily induced by even a low current, and the operation speed of the phase change memory device is improved.

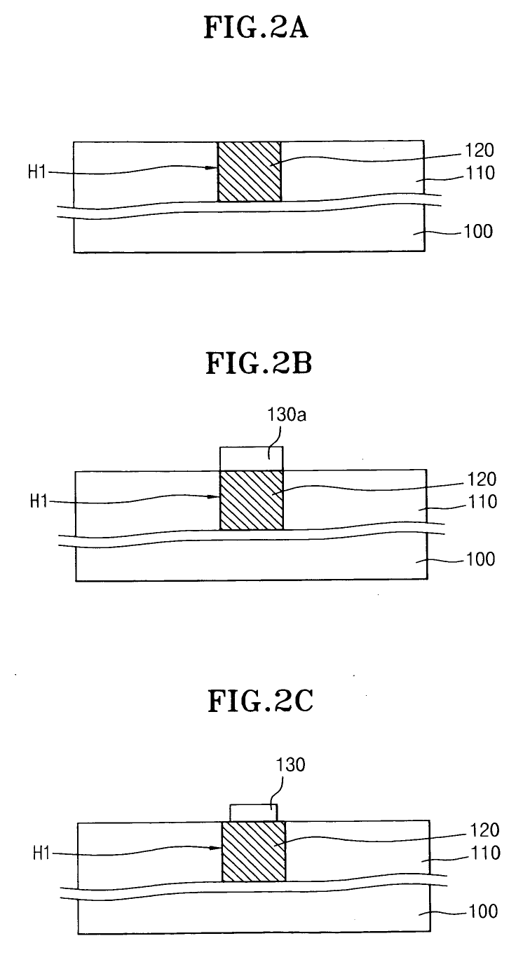

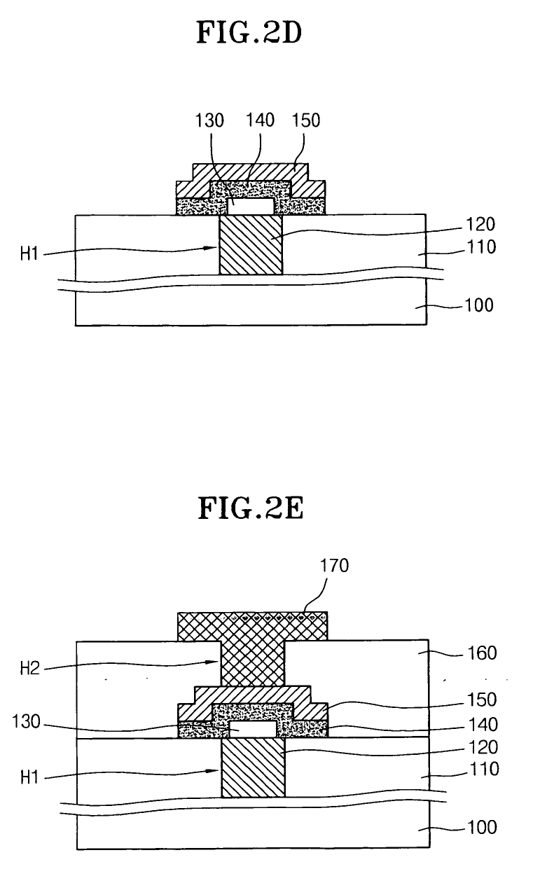

FIGS. 2A to 2E shows cross-sectional views of a method of manufacturing a phase change memory device according to a preferred embodiment of the present invention.

Referring to FIG. 2A, a substructure (not shown) including a transistor, etc. is formed on a semiconductor substrate 100, and a first insulating interlayer 110 is formed in such a manner so as to cover the substructure. The first insulating interlayer 110 is etched to form a first contact hole H1. The first contact hole H1 is filled with an electrically conductive layer to thereby form a plug-shaped lower electrode 120. The size of the plug-shaped lower electrode 120, that is, the size of the first contact hole H1, is set to a size allowing for easy formation of the plug-shaped lower electrode within the limit of the exposing process.

Referring to FIG. 2B, an insulating layer 130a, which is patterned to be at least of an identical size as the lower electrode 120, is formed on the lower electrode 120. In this process, since the patterned insulating layer 130a is about or at least the same size of the lower electrode 120, a fine patterning process is not required in the formation of the patterned insulating layer 130a, and therefore there is no difficulty in the process.

Referring to FIG. 2C, the patterned insulating layer 130a is isotropically etched using wet etching to thereby form an insulating layer pattern 130, which is formed on the middle portion of the lower electrode 120 and exposes an edge portion thereof. Here, in the isotropic etching of the patterned insulating layer 130a, only the patterned insulating layer 130a must be selectively etched, while the first insulating interlayer 110 must not be etched. As a result, the patterned insulating layer 130a must be made of a different material than that of the first insulating interlayer 110. Thus, the first insulating interlayer 110 is made of any one oxide layer selected from the group consisting of TEOS, HDP and HLD layers, and the patterned insulating layer 130a is made of any one oxide layer selected from the group consisting of HSG, PSG, USG and SOG layers. Alternatively, the first insulating interlayer 110 is made of an oxide layer, and the patterned insulating layer 130a is made of a nitride layer.

Referring to FIG. 2D, a phase change material layer and an electrically conductive layer are formed in sequence on the first insulating interlayer 110 including the insulating layer pattern 130. The electrically conductive layer and the phase change material layer are etched to form a phase change layer 140, which covers the insulating layer pattern 130 and comes in contact with the edge portion of the lower electrode 120, and the upper electrode 150.

Referring to FIG. 2E, a second insulating interlayer 160 is formed on the first insulating interlayer 110 such that the laminated pattern of the phase change layer 140 and the upper electrode 150 are covered with the second insulating interlayer 160. The second insulating interlayer 160 is etched to form a second contact hole H2 through which the upper electrode 150 is exposed. A bit line 170, which makes contact with the upper electrode 150 through the second contact hole H2, is formed on the second insulating interlayer 160.

Thereafter, although not shown in the drawings, the phase change memory device according to this embodiment is completed by successively performing a series of known subsequent processes.

In this way, the present invention can bring the phase change layer into contact with only the edge portion of the lower electrode by forming the insulating layer pattern sized smaller than the plug-shaped lower electrode on the lower electrode, thus reducing the contact area between the lower electrode and the phase change layer. Particularly, the insulating layer pattern initially has a similar size to that of the lower electrode and then has a smaller size through a subsequent isotropic etching process. Therefore, the present invention can reduce the contact area between the lower electrode and the phase change layer without performing a fine patterning process, thereby lowering the programming current of the phase change memory device and improving its operation speed.

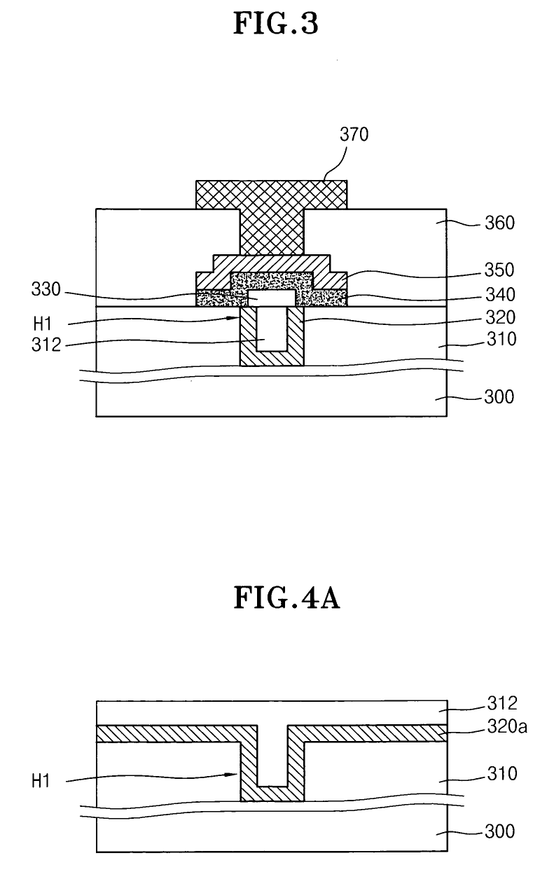

In the above-described embodiment of the present invention, the lower electrode is formed in the shape of a plug, but it may be formed in a cylindrical shape, as illustrated in FIG. 3.

FIG. 3 shows a cross-sectional view of a phase change memory device according to another preferred embodiment of the present invention. The phase change memory device according to this embodiment of the present invention includes a cylindrical-shaped lower electrode 320, a phase change layer 340 formed in such a manner so as to come in contact with the top portion of the cylindrical-shaped lower electrode 320, and an upper electrode 350 formed on the phase change layer 340.

The cylindrical-shaped lower electrode 320 is formed along the surface of the first contact hole H1 within the first insulating interlayer 310. The remaining portion of the contact hole H1, except for the portion occupied by the cylindrical-shaped lower electrode 320, is filled with an insulating layer 312. An insulating layer pattern 330 is formed on the insulating layer 312 and a portion of the cylindrical-shaped lower electrode 320 adjacent thereto. The insulating layer pattern 330 is sized larger than the insulating layer 312 and smaller than the first contact hole H1. The phase change layer 340 is formed in such a manner so as to cover the insulating layer pattern 330 and to come in contact with the exposed top portion, that is, the exposed upper edge portion of the cylindrical-shaped lower electrode 320.

The reference numeral 360 designates a second insulating interlayer formed in such a manner so as to cover the laminated pattern of the phase change layer 340 and the upper electrode 350, and the reference numeral 370 designates a bit line formed in such a manner so as to come in contact with the upper electrode 350.

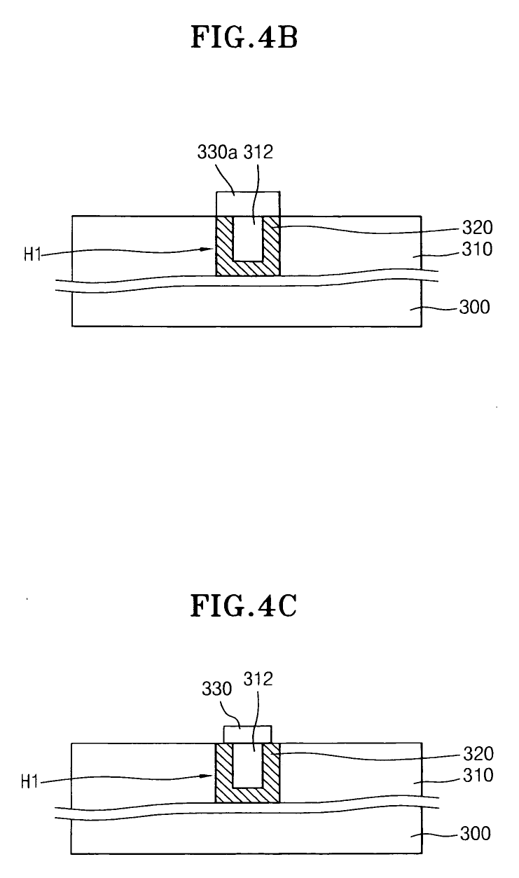

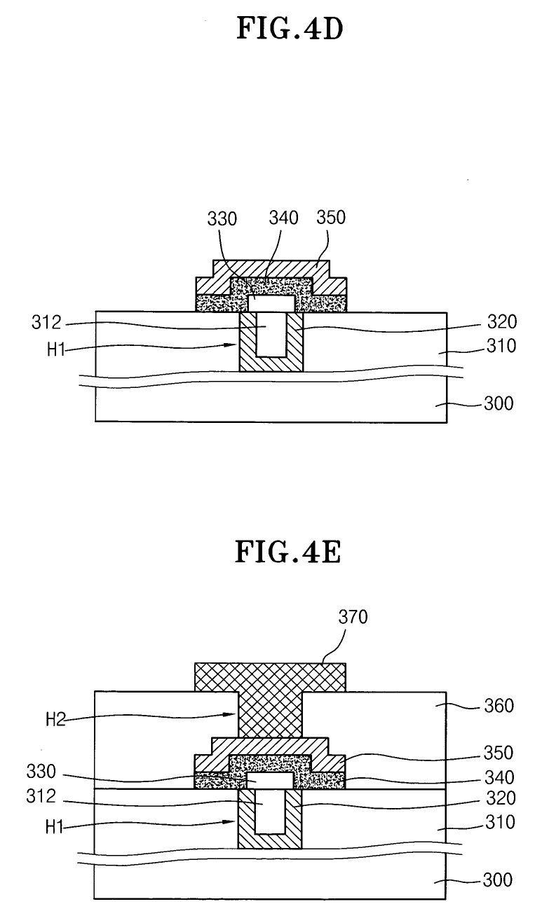

FIGS. 4A to 4E illustrate step-by-step sectional views of the method of manufacturing the phase change memory device according to another preferred embodiment of the present invention.

Referring to FIG. 4A, there is provided a semiconductor substrate 300 in which a substructure (not shown), including a transistor, etc. is formed and a first insulating interlayer 310 is formed so as to cover the substructure. The first insulating interlayer 310 is etched to form a first contact hole H1. On the first insulating interlayer 310 including the surfaces of the first contact hole H1, an electrically conductive layer 320a for a lower electrode is formed to be of a thickness such that the first contact hole H1 is not filled with the electrically conductive layer 320a. An insulating layer 312 is formed on the electrically conductive layer 320a for a lower electrode such that the first contact hole H1 is filled with the insulating layer 312.

Referring to FIG. 4B, the insulating layer 312 and the electrically conductive layer 320a for a lower electrode are subjected to CMP until the first insulating interlayer 310 is exposed, thereby forming a cylindrical-shaped lower electrode 320 within the first contact hole H1. During this process, the insulating layer 312 remains such that it fills the first contact hole H1 except for the portion occupied by the cylindrical-shaped lower electrode 320. An insulating layer 330a, which is patterned to be at least the same size as the first contact hole H1, is formed on the cylindrical-shaped lower electrode 320 and the remaining insulating layer 312.

Referring to FIG. 4C, the patterned insulating layer 330a is isotropically etched to form an insulating layer pattern 330 exposing the the upper edge portion of the cylindrical-shaped lower electrode 320.

In the isotropic etching of the patterned insulating layer 330a, only the patterned insulating layer 330a must be selectively etched, while the first insulating interlayer 310 must not be etched. Thus, the first insulating interlayer 310 and the patterned insulating layer 330a are made of different materials. For example, the first insulating interlayer 310 is made of any one oxide layer selected from the group consisting of TEOS, HDP and HLD layers, and the patterned insulating layer 330a is made of any one oxide layer selected from the group consisting of HSG, PSG, USG and SOG layers. Alternatively, the first insulating interlayer 310 is made of an oxide layer, and the patterned insulating layer 330a is made of a nitride layer.

Referring to FIG. 4D, a phase change material layer and an electrically conductive layer are formed in sequence on the first insulating interlayer 310 including the insulating layer pattern 330. The electrically conductive layer and the phase change material layer are subsequently etched to form a phase change layer 340, which covers the insulating layer pattern 330 and comes in contact with the edge portion of the cylindrical-shaped lower electrode 320, and the upper electrode 350.

Referring to FIG. 4E, a second insulating interlayer 360 is formed on the first insulating interlayer 310 such that the laminated pattern of the phase change layer 340 and the upper electrode 350 are covered with the second insulating interlayer 360. aThe second insulating interlayer 360 is then etched to form a second contact hole H2 through which the upper electrode 350 is exposed. A bit line 370, which is in contact with the upper electrode 350 through the second contact hole H2, is formed on the second insulating interlayer 360.

Thereafter, although not shown in the drawings, the phase change memory device according to this embodiment is completed by successively performing a series of known subsequent processes.

Along with the phase change memory device according to the afore-described embodiment, the phase change memory device according to this embodiment can also easily reduce the contact area between the lower electrode and the phase change layer without performing a fine patterning process, thereby lowering the current required for the phase change of the phase change layer and improving the operation speed of the phase change memory device.

In addition, although not shown in the drawings, another embodiment of the present invention may be proposed, in which the insulating layer pattern 330 in FIG. 4 is not formed. In such an embodiment, by reducing the thickness of the electrically conductive layer for the lower electrode, the contact area between the lower electrode and the phase change layer is reduced without forming the insulating layer pattern.

As described above, according to the phase change memory device and the manufacturing method of the present invention, a phase change layer makes contact with only the edge portion of the lower electrode through the formation of an insulating pattern, such that the contact area between the lower electrode and the phase change layer is reduced. Particularly, since an insulating layer pattern exposing only the edge portion of the lower electrode is formed by means of an isotropic etching process, a fine patterning process is not required. Thus, the contact area between the lower electrode and the phase change layer can be easily reduced while conventional exposing equipment is used in its entirety, and therefore the development of new equipment is unnecessary. Further, a problem of uniformity deterioration associated with the fine patterning process can be solved. Consequently, the present invention can lower the programming current and improve the operation speed of the phase change memory device.

Although preferred embodiments of the present invention have been described for illustrative purposes, the present invention is not limited thereto, and those skilled in the art will appreciate that various modifications, additions and substitutions are possible, without departing from the scope and spirit of the invention as disclosed in the accompanying claims.

What is claimed is:

1. A phase change memory device comprising a data storage unit comprising:
a lower electrode having an upper surface area;
an insulating layer pattern formed on a portion of the lower electrode upper surface area;
a phase change layer formed on the insulating layer pattern and contacting a portion of the lower electrode uncovered by the insulating layer; and
an upper electrode formed on the phase change layer, wherein the phase change layer is capable of changing phase when current is applied between the lower and upper electrodes.

2. A phase change memory device of claim 1 comprising:
a semiconductor substrate;
a first insulating interlayer having a contact hole formed on the semiconductor substrate,
wherein the lower electrode is formed within the contact hole of the first insulating interlayer,
wherein area of the insulating layer pattern is smaller than the lower electrode upper surface area such that an edge portion of the lower electrode is exposed, and
wherein the phase change layer covers the insulating layer pattern and contacts the exposed edge portion of the lower electrode.

3. The phase change memory device of claim 2, wherein the lower electrode is formed in the shape of a plug with which the contact hole is entirely filled.

4. The phase change memory device of claim 2, wherein the lower electrode is formed in a cylindrical shape along the contact hole surface.

5. The phase change memory device of claim 2, further comprising an insulating layer formed in such a manner so as to fill the contact hole except for the contact hole portion occupied by the cylindrical-shaped lower electrode.

6. The phase change memory device of claim 2, wherein the first insulating interlayer includes at least one oxide layer of TEOS, HDP and HLD layers, and wherein the insulating layer pattern includes at least one oxide layer of HSG, PSG, USG and SOG layers.

7. The phase change memory device of claim 2, wherein the first insulating interlayer is made of an oxide layer, and the insulating layer pattern is made of a nitride layer.

8. The phase change memory device of claim 2, further comprising:
a second insulating interlayer formed to cover the phase change layer and the upper electrode; and
a bit line formed on the second insulating interlayer and coming in contact with the upper electrode.

9. A method of manufacturing a phase change memory device, the method comprising the steps of:
forming a first insulating interlayer, which has a contact hole, on a semiconductor substrate;
forming a lower electrode within the contact hole;
forming an insulating layer pattern on the lower electrode such that the insulating layer pattern is sized smaller than the lower electrode and exposes an edge portion of the lower electrode;
forming a phase change material layer and an electrically conductive layer for an upper electrode in sequence on the first insulating interlayer including the insulating layer pattern; and
etching the phase change material layer and the electrically conductive layer for the upper electrode to thereby form the upper electrode and a phase change layer which covers the insulating layer pattern and comes in contact with the exposed edge portion of the lower electrode.

10. The method of claim 9, wherein the lower electrode is formed in the shape of a plug with which the contact hole is entirely filled.

11. The method of claim 9, wherein the lower electrode is formed in a cylindrical shape along the contact hole surface.

12. The method of claim 11, wherein an insulating layer is formed to fill the contact hole except for the contact hole portion occupied by the cylindrical-shaped lower electrode.

13. The method of claim 12, wherein the cylindrical-shaped lower electrode and the insulating layer are formed by the steps of:
forming an electrically conductive layer for the lower electrode on the contact hole surface and the first insulating interlayer such that the contact hole is not filled with the electrically conductive layer;
forming the insulating layer on the electrically conductive layer for the lower electrode such that the contact hole is filled with the insulating layer; and
chemical-mechanical-polishing (CMP) the insulating layer and the electrically conductive layer for the lower electrode until the first insulating interlayer is exposed.

14. The method of claim 9, wherein the step of forming the insulating layer pattern comprises the steps of:
forming an insulating layer, which is patterned to be at least the same size as the lower electrode, on the lower electrode; and
isotropically etching a partial thickness of the insulating layer to thereby expose the edge portion of the lower electrode.

15. The method of claim 9, wherein the first insulating interlayer includes at least one oxide layer of TEOS, HDP and HLD layers, and the insulating layer pattern includes at least one oxide layer of HSG, PSG, USG and SOG layers.

16. The method of claim 9, wherein the first insulating interlayer is made of an oxide layer, and the insulating layer pattern is made of a nitride layer.

17. The method of claim 9, further comprising the steps of:
after forming the phase change layer and the upper electrode, forming a second insulating interlayer such that the phase change layer and the upper electrode are covered with the second insulating interlayer; and
forming a bit line on the second insulating interlayer such that the upper electrode comes in contact with the bit line.
